(19) United States
(12) Patent Application Publication
(10) Pub. No.: US 2025/0380539 A1
(43) Pub. Date: Dec. 11, 2025

(54) INFRARED OPTICAL ELEMENT

(71) Applicant: Asahi Kasei Microdevices Corporation, Tokyo (JP)

(72) Inventor: Kengo SASAYAMA, Tokyo (JP)

(73) Assignee: Asahi Kasei Microdevices Corporation, Tokyo (JP)

(21) Appl. No.: 19/227,498

(22) Filed: Jun. 4, 2025

(30) Foreign Application Priority Data
Jun. 7, 2024 (JP) 2024-093285
Jun. 21, 2024 (JP) 2024-100799
May 21, 2025 (JP) 2025-085203
May 21, 2025 (JP) 2025-085204

(51) Int. Cl. H10H 20/821; H10F 39/00; H10F 39/18; H10F 77/14; H10F 77/20; H10H 20/831; H10H 20/832; H10H 29/14; H10H 29/80

(52) U.S. Cl. CPC H10H 20/821; H10F 39/184; H10F 39/811; H10F 77/147; H10F 77/206; H10H 20/831; H10H 20/835; H10H 29/142; H10H 29/8321

(57) ABSTRACT

An infrared optical element includes a substrate (10) and unit elements in each of which a first conductive semiconductor layer (123), an active layer (122), and a second conductive semiconductor layer (121) configure a mesa structure. The unit element includes a first contact portion (125H) that electrically connects the first conductive semiconductor layer and a first contact electrode portion, and a second contact portion (124H) that electrically connects the second conductive semiconductor layer and a second contact electrode portion. The ratio between the shortest distance from an end of an upper flat portion of the mesa structure to an end of the first contact portion and the thickness of the first conductive semiconductor layer is 14 or more, and the area of the first contact portion is 6% or more of the area of the upper flat portion.

### CROSS-REFERENCE TO RELATED APPLICATION

This application claims priority to Japanese Patent Application Nos. 2024-093285 (filed on Jun. 7, 2024), 2024-100799 (filed on Jun. 21, 2024), 2025-085203 (filed on May 21, 2025), and 2025-085204 (filed on May 21, 2025), and the entire contents of which are incorporated herein by reference.

### TECHNICAL FIELD

The present disclosure relates to an infrared optical element.

### BACKGROUND

In general, infrared light in a long wavelength band of 2 μm or more is used in gas sensors due to the effect of infrared absorption by gases. In particular, the region of wavelengths from 2.5 μm to 10 μm, in which there are many absorption bands specific to various types of gases, is a wavelength band suitably used in gas sensors. Non-dispersive infrared gas sensors are known that measure a desired gas concentration by detecting the absorption amount of infrared light of a specific wavelength by taking advantage of the fact that the wavelength of the infrared light to be absorbed differs depending on the type of gas.

Here, the performance of apparatuses such as gas sensors can be improved by using infrared optical elements (high-performance infrared optical elements) that have high sensitivity or high luminous efficiency. The high-performance infrared optical element can be achieved by connecting a large number of photoelectric conversion elements (e.g., photodiodes) in series. For example, Patent Literature (PTL) 1 discloses an optical device with improved reliability, which has such a structure that a large number of photoelectric conversion elements are connected in series.

### CITATION LIST

### Patent Literature

PTL 1: JP 5352857 B2

### SUMMARY

Here, infrared optical elements that use photoelectric conversion elements with mesa structures are known. In such infrared optical elements, a resistance drop may occur due to side leakage (leakage of current to sides) in the mesa structures. To reduce the side leakage, for example, the distance to the sides may be increased by reducing the size of an electrode. On the other hand, when the size of the electrode is too small, there is a risk of reducing a signal-to-noise ratio (SNR). For this reason, a design method for photoelectric conversion elements that can achieve both an improved resistance drop and an increased SNR is desired.

Considering these circumstances, the present disclosure aims at providing an infrared optical element that can achieve both an improved resistance drop and an increased SNR.

(1) An infrared optical element according to one embodiment of the present disclosure includes:
a substrate; and
a unit element,
wherein
the unit element includes:
   a second conductive semiconductor layer disposed on the substrate;
   an active layer disposed on the second conductive semiconductor layer; and
   a first conductive semiconductor layer disposed on the active layer,
the first conductive semiconductor layer, the active layer, and the second conductive semiconductor layer configure a mesa structure,
the unit element further includes:
   a first contact portion that electrically connects the first conductive semiconductor layer and a first contact electrode portion; and
   a second contact portion that electrically connects the second conductive semiconductor layer and a second contact electrode portion,
the ratio (A/B) between the shortest distance A from an end of an upper flat portion of the mesa structure to an end of the first contact portion and the thickness B of the first conductive semiconductor layer is 14 or more, and
the area of the first contact portion is 6% or more of the area of the upper flat portion.

(2) An infrared optical element according to one embodiment of the present disclosure includes:
a substrate; and
a unit element,
wherein
the unit element includes:
   a second conductive semiconductor layer disposed on the substrate;
   an active layer disposed on the second conductive semiconductor layer; and
   a first conductive semiconductor layer disposed on the active layer,
the first conductive semiconductor layer, the active layer, and the second conductive semiconductor layer configure a mesa structure,
the unit element further includes:
   a first contact portion that electrically connects the first conductive semiconductor layer and a first contact electrode portion; and
   a second contact portion that electrically connects the second conductive semiconductor layer and a second contact electrode portion,
the shortest distance A from an end of an upper flat portion of the mesa structure to an end of the first contact portion is 7 μm or more, and
the area of the first contact portion is 6% or more of the area of the upper flat portion.

(3) As one embodiment of the present disclosure, in (1) or (2), the area of the first contact portion is 3 or more times the area of the second contact portion.

(4) As one embodiment of the present disclosure, in any one of (1) to (3), 50% or more of the area of the upper flat portion of the mesa structure is covered by the first contact electrode portion.

(5) As one embodiment of the present disclosure, in (2), the shortest distance A is 10 μm or more.

(6) As one embodiment of the present disclosure, in any one of (1) to (5), the area of the first contact portion is 5 or more times the area of the second contact portion.

(7) As one embodiment of the present disclosure, in any one of (1) to (6), the area of the first contact portion is 65% or less of the area of an electrode covering area inside the upper flat portion.

(8) As one embodiment of the present disclosure, in any one of (1) to (7), the first contact electrode portion and the second contact electrode portion contain titanium as a material.

(9) As one embodiment of the present disclosure, in any one of (1) to (8), the unit element includes multiple first contact portions.

(10) As one embodiment of the present disclosure, in any one of (1) to (9), the area of the first contact portion is 13% or more of the area of the upper flat portion.

According to the present disclosure, it is possible to provide an infrared optical element that can achieve both an improved resistance drop and an increased SNR.

### BRIEF DESCRIPTION OF THE DRAWINGS

In the accompanying drawings:

FIG. 1 is a schematic configuration diagram (plan view) of an infrared optical element according to an embodiment of the present disclosure;

FIG. 2 is a partial cross-sectional view of the infrared optical element in FIG. 1;

FIG. 3 is a diagram illustrating a first wiring pattern;

FIG. 4 is a diagram illustrating a second wiring pattern;

FIG. 5 is a diagram illustrating a third wiring pattern;

FIG. 6 is a partial cross-sectional view of the infrared optical element in FIG. 1;

FIG. 7 is a diagram that explains configurations of contact portions and the like in a mesa structure;

FIG. 8A is a diagram illustrating a configuration of an upper portion of a mesa structure corresponding to Number 1 in Table 4;

FIG. 8B is a diagram illustrating a configuration of an upper portion of a mesa structure corresponding to Number 2 in Table 4;

FIG. 8C is a diagram illustrating a configuration of an upper portion of a mesa structure corresponding to Number 3 in Table 4;

FIG. 8D is a diagram illustrating a configuration of an upper portion of a mesa structure corresponding to Number 4 in Table 4;

FIG. 8E is a diagram illustrating a configuration of an upper portion of a mesa structure corresponding to Number 5 in Table 4; and

FIG. 8F is a diagram illustrating a configuration of an upper portion of a mesa structure corresponding to Number 6 in Table 4;

FIG. 9 is a diagram illustrating a fourth wiring pattern;

FIG. 10 is a diagram illustrating a fifth wiring pattern;

FIG. 11 is a diagram illustrating a sixth wiring pattern.

### DETAILED DESCRIPTION

Embodiments of the present disclosure will be described below with reference to the drawings. In the following drawings, the same reference numerals are assigned to the same portions. However, the drawings are schematic. For example, the relationship between thickness and plane dimension is different from the actual one. Further, the following embodiments exemplify objects that embody the technical idea of the present disclosure, and do not limit the material, shape, structure, arrangement, and the like of components to those described below.

### First Embodiment

### (Infrared Optical Element)

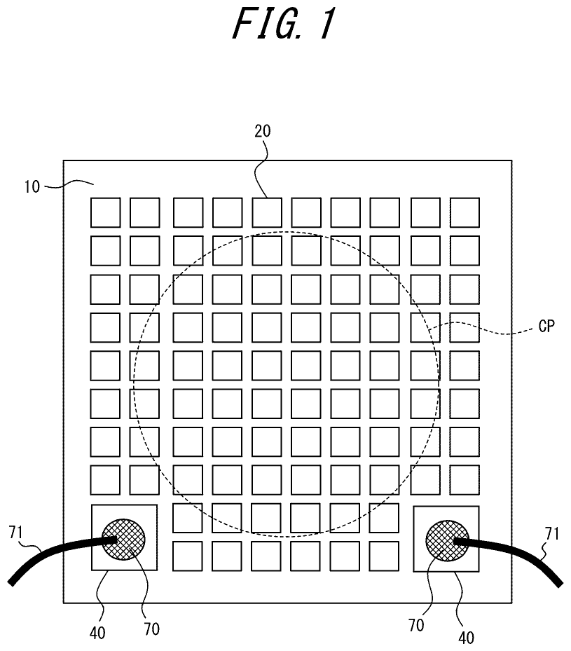

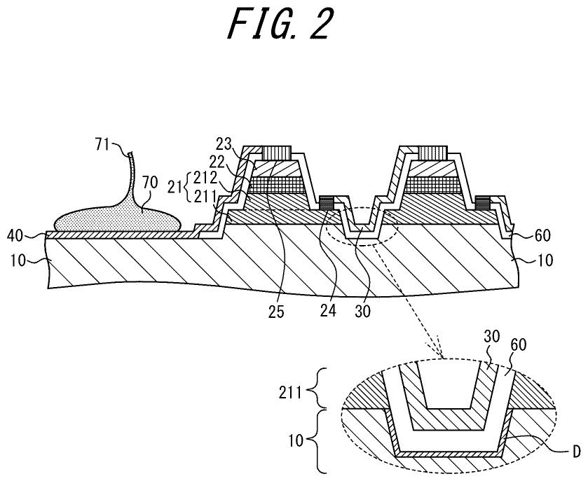

FIG. 1 is a schematic configuration diagram illustrating an infrared optical element according to a first embodiment. FIG. 1 is a plan view. FIG. 2 is a partial cross-sectional view of the infrared optical element illustrated in FIG. 1, and illustrates multiple unit elements 20 that are electrically connected to a pad electrode 40. The infrared optical element includes a substrate 10 and unit elements 20. The infrared optical element according to this embodiment further includes pad electrodes 40. The infrared optical element is an infrared light receiving element or an infrared light emitting element, and is a collective name therefor. The infrared optical element performs emission and reception of infrared light. Here, the emission and reception of light means having at least one of the function of receiving light or the function of emitting light. The infrared light receiving element is realized with the structure illustrated in FIGS. 1 and 2, and the infrared light emitting element is realized with the same structure. The unit elements 20 are photoelectric conversion elements, and in this embodiment, are photodiodes (PDs) or light emitting diodes (LEDs) of minimal configurations.

The infrared optical element according to this embodiment can be used as a component of a gas sensor (concentration measurement apparatus) that measures the concentration of a target gas, for example. The gas sensor may be, for example, a non-dispersive infrared absorption (NDIR) type, or a photoacoustic type that measures the concentration of a gas by picking up the vibrations of gas molecules that have absorbed light, using a high-performance microphone. Not limited to the gas sensor, the infrared optical element according to this embodiment may be used in an infrared radiation thermometer, infrared spectral imaging, a human detection sensor, or the like.

The infrared optical element according to this embodiment has such a configuration that a large number of photoelectric conversion elements (multiple unit elements 20) are connected in series to have high sensitivity or high luminous efficiency. However, the infrared optical element only needs to include one or more unit elements 20. Respective unit elements 20 that are located at ends of the multiple unit elements 20 connected in series are electrically connected to different pad electrodes 40. For example, there may be multiple pad electrodes 40, and the respective pad electrodes 40 may be located at end portions of the infrared optical element. In the example of FIG. 1, the respective multiple pad electrodes 40 are located at different end portions of the infrared optical element, but can be arranged side by side at the same end portion. The pad electrodes 40, which do not contribute to the emission and reception of the infrared light, are arranged at the end portions that are outside a central portion (CP) of the infrared optical element. The end portions are not limited to any of the four corners, but only need to be adjacent to any of the four sides. For example, when the infrared optical element is a light receiving element, this configuration allows a greater number of photodiodes to be arranged at the central portion (CP) on which the infrared light is concentratedly incident, which increases the sensitivity compared to a configuration in which the pad electrodes 40 are arranged at part of the central portion (CP). Also, for example, when the infrared optical element is a light emitting element, this configuration allows only light emitting diodes to be arranged in the central portion (CP), which forms a more uniform luminance plane compared to a configuration in which the pad electrodes 40 are present in part of the central portion (CP). Compared to light emitting elements with irregular (partially non-emitting) light emitting surfaces, light emitting elements with uniform light emitting surfaces ease optical design in apparatuses that use the light emitting elements.

### (Substrate)

The substrate 10 according to this embodiment has no restrictions on doping by donor impurities or acceptor impurities. However, from the viewpoint of enabling the multiple unit elements 20 formed on the substrate 10 to be connected in series, it is desirable that the substrate 10 is semi-insulating or can be insulated and separated from first conductive semiconductor layers 21.

Here, when light is incident on or emitted from the side of the substrate 10, it is necessary to use, as the substrate 10, a material with a larger band gap than active layers 22. As an example, the substrate 10 may be a GaAs substrate, a Si substrate, an InP substrate, or an InSb substrate, but is not limited to these.

### (Unit Element)

As described above, there may be multiple unit elements 20. Each of the multiple unit elements 20 includes a first conductive semiconductor layer 21 disposed on the substrate 10, an active layer 22 disposed on the first conductive semiconductor layer 21, and a second conductive semiconductor layer 23 disposed on the active layer 22. As described above, the infrared optical element according to this embodiment is configured with the multiple unit elements 20 that are electrically connected in series.

### (Mesa Structure)

As illustrated in FIG. 2, the first conductive semiconductor layer 21, the active layer 22, and the second conductive semiconductor layer 23 form a mesa structure.

The mesa structure is not particularly limited as long as the mesa structure includes a photodiode structure with a PN junction or a PIN junction. The first conductive semiconductor layer 21 and the second conductive semiconductor layer 23 are of opposite conductive types. For example, when the first conductive semiconductor layer 21 is an n-type, the second conductive semiconductor layer 23 is a p-type. For example, when the first conductive semiconductor layer 21 is a p-type, the second conductive semiconductor layer 23 is an n-type. The material of the first conductive semiconductor layer 21 and the second conductive semiconductor layer 23 is InSb, InAsSb, AlInSb, or the like, but is not limited to these. The first conductive semiconductor layer 21 and the second conductive semiconductor layer 23 may have laminated structures made of multiple materials. The active layer 22 preferably contains In and Sb, as constituent elements. The material of the active layer 22 may contain InSb. As a specific example, the material of the active layer 22 may be InSb or AlInSb.

### (Contact Electrode)

The infrared optical element according to this embodiment includes first contact electrode portions 24 each disposed on a first region 211 of the first conductive semiconductor layer 21, and second contact electrode portions 25 each disposed on the second conductive semiconductor layer 23. The material of the contact electrodes (the first contact electrode portions 24 or the second contact electrode portions 25) preferably has low contact resistance to the semiconductor layers and low electric resistance. As a specific example, the material of the contact electrodes may be Ti, Ni, Pt, Cr, Al, Cu, Au, or the like. The contact electrodes may be made of laminates of multiple types of materials.

### (Internal Wiring Portion)

The infrared optical element according to this embodiment includes internal wiring portions 30 each of which connects the first contact electrode portion 24 of a single unit element 20 and the second contact electrode portion 25 of another unit element 20 that is adjacent and electrically connected to that unit element 20. In other words, the internal wiring portions 30 electrically connect the multiple unit elements 20 in series. The material of the internal wiring portions 30 preferably has low electric resistance. As a specific example, the material of the internal wiring portions 30 may be Ti, Ni, Pt, Cr, Al, Cu, Au, or the like.

### (Insulating Portion)

The unit elements 20 of the infrared optical element according to this embodiment may further include an insulating portion 60 so that side surfaces of the mesa structures are not electrically connected to the internal wiring portions 30 in a direct manner. The insulating portion 60 is disposed between first mesa structures (each constituted of a second region 212, the active layer 22, and the second conductive semiconductor layer 23) and the internal wiring portions 30, and between second mesa structures (each constituted of the first region 211 and part of the substrate 10) and the internal wiring portions 30. The material of the insulating portion 60 may be silicon nitride, silicon oxide, aluminum oxide, or the like, but is not limited to these. The insulating portion 60 may be made of a laminate of multiple types of materials.

### (Pad Electrode)

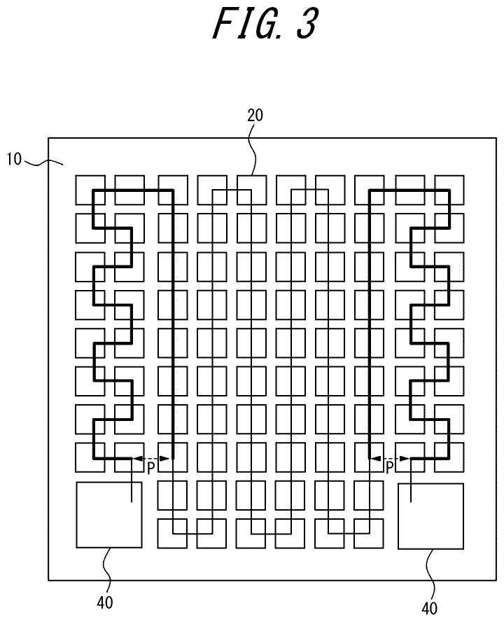

As described above, there are multiple pad electrodes 40 each of which is arranged at an end portion, which is outside the central portion (CP), of the infrared optical element. The pad electrode 40 is electrically connected to the first contact electrode portion 24 or the second contact electrode portion 25 of a unit element 20 located at an end of the multiple unit elements 20 connected in series. In other words, within the infrared optical element, the multiple pad electrodes 40 and the multiple unit elements 20 are electrically connected in series with the pad electrodes 40 being located at both ends (see FIG. 3). The pad electrodes 40 are also electrically connected to a device or the like outside the infrared optical element via connection portions 70 and connection wires 71.

The material of the pad electrodes 40 preferably has low electric resistance. As a specific example, the material of the pad electrodes 40 may be Ti, Ni, Pt, Cr, Al, Cu, Au, or the like. The pad electrodes 40 may be made of a material different from that of the contact electrodes.

### (Connection Portion)

As described above, the connection portions 70 are provided for electrically connecting to the outside. As a specific example, the connection portions 70 may be made of metal and conductive adhesive. For example, the connection portions 70 and the connection wires 71 may be wire-bonded onto the pad electrodes 40.

### (Creepage Distance)

Although adjacent unit elements 20 are arranged at a predetermined distance from each other, as illustrated in FIG. 2, a substantial distance between the unit elements 20 can be increased by cutting the substrate 10 by etching or the like, to improve insulation. Therefore, this embodiment uses not a distance viewed from above, but a creepage distance D, which includes sides (slopes) of an insulating part (substrate 10 in this embodiment), as a distance between the unit elements 20 for evaluating insulation. In FIG. 2, the creepage distance D is illustrated as the length of a surface of the substrate 10 between the unit elements 20, that is, the length of the surface in a portion in contact with the insulating portion 60. However, the creepage distance D is defined not only for adjacent unit elements 20 that are electrically connected, but also for adjacent unit elements 20 that are not electrically connected. In other words, for all adjacent unit elements 20, the shortest distance of a surface (slopes and bottom) of the insulating part between the unit elements 20 is the creepage distance D.

Here, in the infrared optical element according to this embodiment, the multiple unit elements 20 are connected in series to achieve high sensitivity or high luminous efficiency, but in order to improve reliability, it is necessary to improve resistance to short-circuiting caused by ESD. First, a method of providing an infrared optical element with improved resistance to short-circuiting caused by ESD will be described below with illustrating a specific wiring pattern (first wiring pattern).

FIG. 3 is a diagram illustrating a first wiring pattern. The infrared optical element in FIG. 3 is illustrated in a plan view in the same manner as FIG. 1, and connection portions 70 and connection wires 71 are omitted for ease of viewing. In FIG. 3, a wiring pattern (first wiring pattern) with which the multiple pad electrodes 40 and the multiple unit elements 20 are electrically connected in series is illustrated in a solid line. Part of the solid line, which is the wiring pattern, is illustrated by bold lines. The creepage distance D between adjacent unit elements 20 is constant in general, but the magnitude of a voltage applied between the adjacent unit elements 20 differs depending on the wiring pattern. In other words, if a voltage Va is applied between the multiple pad electrodes 40, a potential difference that is equal to the number of stages between the adjacent unit elements 20 connected (electrically connected) by the wiring pattern multiplied by “Va/the total number of the unit elements 20” occurs. In the example in FIG. 3, the total number of unit elements 20 is 92. In the first wiring pattern in FIG. 3, a maximum potential difference Vb is applied between unit elements 20 indicated by P, so these points are the weakest in resistance to short-circuiting. In the example in FIG. 3, as indicated by the bold lines, the number of stages between the unit elements 20 is 23, so the maximum potential difference Vb is expressed as “Va×(23/92).” Therefore, by identifying the points (P in FIG. 3) with low resistance according to the wiring pattern and determining whether the maximum potential difference Vb and the creepage distance D satisfy a predetermined relationship, it is possible to efficiently select an infrared optical element with high resistance to short-circuiting caused by ESD. The inventor has actively examined and confirmed that the infrared optical element can be determined to have high resistance to short-circuiting caused by ESD when the following relationships between the wiring pattern, the voltage Va, the maximum potential difference Vb, and the creepage distance D are satisfied. This method can also be used in situations such as before the precise characteristics (e.g., resistance value) of each unit element 20 have been measured.

First, for the wiring pattern, the infrared optical element is configured to satisfy the condition that 70 or more and 200 or less electrically connected unit elements 20 are arranged to electrically connect between the multiple pad electrodes 40. When the number of unit elements 20 is less than 70, a voltage applied to each unit element 20 may become too high. When the number of unit elements 20 exceeds 200, the entire size of the infrared optical element may become too large, and fail to meet the demand for miniaturization.

For the voltage Va applied between the multiple pad electrodes 40 and the maximum voltage difference Vb between unit elements 20 adjacent vertically or horizontally, the infrared optical element is configured to satisfy the condition 0.140≤(Vb/Va)≤0.261. The smaller the value of (Vb/Va), the higher the resistance to short-circuiting caused by ESD. On the other hand, when the value of (Vb/Va) is too small, the entire size of the infrared optical element increases. To balance these factors, the condition 0.140≤(Vb/Va)≤0.261 is set. Here, for the purpose of further miniaturization, the infrared optical element may be configured to satisfy the condition 0.190≤(Vb/Va)≤0.261.

For the creepage distance D of the insulating part that is present between the unit elements 20 adjacent vertically or horizontally, the infrared optical element is configured to satisfy the condition 3.5 μm≤D≤6.0 μm. The larger the creepage distance D, the higher the resistance to short-circuiting caused by ESD. On the other hand, when the creepage distance D is too large, the entire size of the infrared optical element increases. To balance these factors, the condition 3.5 μm≤D≤6.0 μm is set. Here, for the purpose of further miniaturization, the infrared optical element may be configured to satisfy the condition 3.5 μm≤D≤4.5 μm. In order to make it easier to satisfy the condition related to the creepage distance D, the adjacent unit elements 20 (the unit elements 20 at the position of P in the example in FIG. 3) that have the maximum potential difference may have a different shape from the other unit elements 20.

Here, for the relationship between the voltage Va, the maximum potential difference Vb, and the creepage distance D, it is possible to summarize the conditions. For example, by defining a range for the ratio between the creepage distance D and the value of (Vb/Va), the condition 13.4 μm≤D/(Vb/Va)≤31.5 μm may be satisfied. This condition corresponds to a combination of 3.5 μm≤D≤6.0 μm and 0.190≤(Vb/Va)≤0.261.

Here, for the first wiring pattern, the number of unit elements 20 (the numbers of unit elements in vertical and horizontal directions when viewed from above) and the like may differ. Table 1 summarizes, for the first wiring pattern in FIG. 3, “the maximum shortcut number of adjacent unit elements” (i.e., the number of stages between unit elements 20 connected by the wiring pattern that produces the above-described maximum potential difference Vb) and the like when the number of unit elements 20 is changed. For example, when the first wiring pattern is adopted, combinations that satisfy the appropriate relationship between the wiring pattern, the voltage Va, the maximum potential difference Vb, and the creepage distance D may be selected from Table 1. The appropriate relationship may be, for example, that 70 or more and 200 or less unit elements 20 are connected in series, and 0.140≤(Vb/Va)≤0.261 is satisfied. In addition, the appropriate relationship may be that 3.5 μm≤D≤6.0 μm is also satisfied. Here, as described above, the condition 0.190≤(Vb/Va)≤0.261 may be used instead of 0.140≤(Vb/Va)≤0.261. The condition 3.5 μm≤D≤4.5 μm may be used instead of 3.5 μm≤D≤6.0 μm. The appropriate relationship may be that 70 or more and 200 or less unit elements 20 are connected in series, and 13.4 μm≤D/(Vb/Va)≤31.5 μm is satisfied.

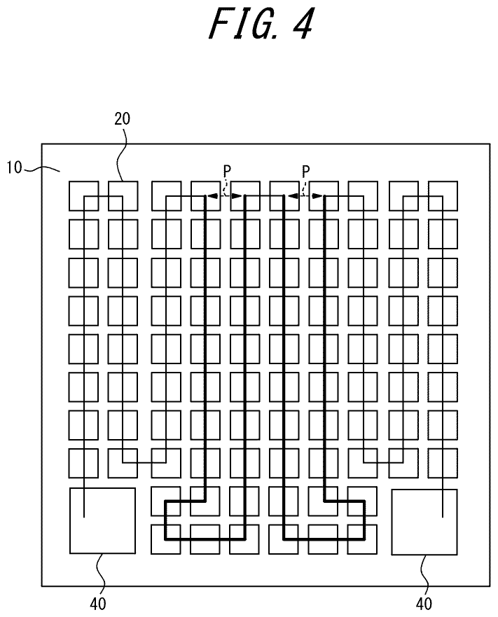

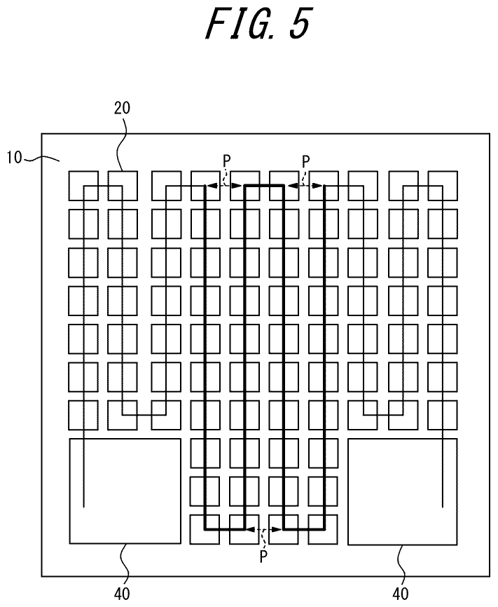

As the wiring pattern, a second wiring pattern illustrated in FIG. 4 or a third wiring pattern illustrated in FIG. 5 may be used, instead of the first wiring pattern. The weakest points in resistance to short-circuiting depend on the structure of the wiring pattern. Therefore, the weakest points (P) in resistance illustrated in FIG. 4 or 5 are different in position from those illustrated in FIG. 3. Furthermore, the size of the pad electrodes 40 is not limited to the equivalent of four unit elements (see FIGS. 3 and 4), and may be, for example, the equivalent of nine unit elements (see FIG. 5), and is not limited to a specific size. The method of the present disclosure can be applied even when the wiring pattern or the size of the pad electrodes 40 is different. Table 2 summarizes, for the second wiring pattern in FIG. 4, “the maximum shortcut number of adjacent unit elements” and the like. Table 3 summarizes, for the third wiring pattern in FIG. 5, “the maximum shortcut number of adjacent unit elements” and the like.

TABLE 1

| Material of Active Layer | AlInSb (Al Composition: 8.9%) | | | | | |
|---|---|---|---|---|---|---|
| Size of Pad Electrode | Equivalent of Four Unit Elements | | | | | |
| Number of Unit Elements (Horizontal) | 8 | 9 | 10 | 11 | 12 | 13 |
| Number of Unit Elements (Vertical) | 8 | 9 | 10 | 11 | 12 | 13 |
| Total Number of Unit Elements | 56 | 73 | 92 | 113 | 136 | 161 |
| Maximum Shortcut Number of Adjacent Unit Elements | 17 | 19 | 23 | 25 | 29 | 31 |
| Vb/Va | 0.3036 | 0.2603 | 0.25 | 0.2212 | 0.2132 | 0.1925 |
| Is Total Number of Unit Elements 70 or more? | No | Yes | Yes | Yes | Yes | Yes |
| Is Total Number of Unit Elements 200 or less? | Yes | Yes | Yes | Yes | Yes | Yes |
| Is 0.140 ≤ Vb/Va ≤ 0.261 Satisfied? | No | Yes | Yes | Yes | Yes | Yes |
| Is 0.190 ≤ Vb/Va ≤ 0.261 Satisfied? | No | Yes | Yes | Yes | Yes | Yes |
| D/(Vb/Va) [μm] *D = 3.5 [μm] | 11.53 | 13.45 | 14.00 | 15.82 | 16.41 | 18.18 |
| D/(Vb/Va) [μm] *D = 4.5 [μm] | 14.82 | 17.29 | 18.00 | 20.34 | 21.10 | 23.37 |
| D/(Vb/Va) [μm] *D = 5.0 [μm] | 16.47 | 19.21 | 20.00 | 22.60 | 23.45 | 25.97 |
| D/(Vb/Va) [μm] *D = 6.0 [μm] | 19.76 | 23.05 | 24.00 | 27.12 | 28.14 | 31.16 |

| Material of Active Layer | AlInSb (Al Composition: 8.9%) | | | | | |
|---|---|---|---|---|---|---|
| Size of Pad Electrode | Equivalent of Four Unit Elements | | | | | |
| Number of Unit Elements (Horizontal) | 14 | 15 | 16 | 17 | 18 | 19 |
| Number of Unit Elements (Vertical) | 14 | 15 | 16 | 17 | 18 | 19 |
| Total Number of Unit Elements | 188 | 217 | 248 | 281 | 316 | 353 |
| Maximum Shortcut Number of Adjacent Unit Elements | 35 | 37 | 41 | 43 | 47 | 49 |
| Vb/Va | 0.1862 | 0.1705 | 0.1653 | 0.153 | 0.1487 | 0.1388 |
| Is Total Number of Unit Elements 70 or more? | Yes | Yes | Yes | Yes | Yes | Yes |
| Is Total Number of Unit Elements 200 or less? | Yes | No | No | No | No | No |
| Is 0.140 ≤ Vb/Va ≤ 0.261 Satisfied? | Yes | Yes | Yes | Yes | Yes | No |
| Is 0.190 ≤ Vb/Va ≤ 0.261 Satisfied? | No | No | No | No | No | No |
| D/(Vb/Va) [μm] *D = 3.5 [μm] | 18.80 | 20.53 | 21.17 | 22.87 | 23.53 | 25.21 |
| D/(Vb/Va) [μm] *D = 4.5 [μm] | 24.17 | 26.39 | 27.22 | 29.41 | 30.26 | 32.42 |
| D/(Vb/Va) [μm] *D = 5.0 [μm] | 26.86 | 29.32 | 30.24 | 32.67 | 33.62 | 36.02 |
| D/(Vb/Va) [μm] *D = 6.0 [μm] | 32.23 | 35.19 | 36.29 | 39.21 | 40.34 | 43.22 |

TABLE 2

| Material of Active Layer | AlInSb (Al Composition: 8.9%) | | | | | |
|---|---|---|---|---|---|---|
| Size of Pad Electrode | Equivalent of Four Unit Elements | | | | | |
| Number of Unit Elements (Horizontal) | 8 | 9 | 10 | 11 | 12 | 13 |
| Number of Unit Elements (Vertical) | 8 | 9 | 10 | 11 | 12 | 13 |
| Total Number of Unit Elements | 56 | 73 | 92 | 113 | 136 | 161 |
| Maximum Shortcut Number of Adjacent Unit Elements | 19 | 19 | 21 | 23 | 25 | 27 |
| Vb/Va | 0.3393 | 0.2603 | 0.2283 | 0.2035 | 0.1838 | 0.1677 |
| Is Total Number of Unit Elements 70 or more? | No | Yes | Yes | Yes | Yes | Yes |
| Is Total Number of Unit Elements 200 or less? | Yes | Yes | Yes | Yes | Yes | Yes |
| Is 0.140 ≤ Vb/Va ≤ 0.261 Satisfied? | No | Yes | Yes | Yes | Yes | Yes |
| Is 0.190 ≤ Vb/Va ≤ 0.261 Satisfied? | No | Yes | Yes | Yes | No | No |
| D/(Vb/Va) [μm] *D = 3.5 [μm] | 10.32 | 13.45 | 15.33 | 17.20 | 19.04 | 20.87 |
| D/(Vb/Va) [μm] *D = 4.5 [μm] | 13.26 | 17.29 | 19.71 | 22.11 | 24.48 | 26.83 |
| D/(Vb/Va) [μm] *D = 5.0 [μm] | 14.74 | 19.21 | 21.90 | 24.57 | 27.20 | 29.81 |
| D/(Vb/Va) [μm] *D = 6.0 [μm] | 17.68 | 23.05 | 26.29 | 29.48 | 32.64 | 35.78 |

| Material of Active Layer | AlInSb (Al Composition: 8.9%) | | | | | |
|---|---|---|---|---|---|---|
| Size of Pad Electrode | Equivalent of Four Unit Elements | | | | | |
| Number of Unit Elements (Horizontal) | 14 | 15 | 16 | 17 | 18 | 19 |
| Number of Unit Elements (Vertical) | 14 | 15 | 16 | 17 | 18 | 19 |
| Total Number of Unit Elements | 188 | 217 | 248 | 281 | 316 | 353 |
| Maximum Shortcut Number of Adjacent Unit Elements | 29 | 31 | 33 | 35 | 37 | 39 |
| Vb/Va | 0.1543 | 0.1429 | 0.1331 | 0.1246 | 0.1171 | 0.1105 |
| Is Total Number of Unit Elements 70 or more? | Yes | Yes | Yes | Yes | Yes | Yes |
| Is Total Number of Unit Elements 200 or less? | Yes | No | No | No | No | No |
| Is 0.140 ≤ Vb/Va ≤ 0.261 Satisfied? | Yes | Yes | No | No | No | No |
| Is 0.190 ≤ Vb/Va ≤ 0.261 Satisfied? | No | No | No | No | No | No |
| D/(Vb/Va) [μm] *D = 3.5 [μm] | 22.69 | 24.50 | 26.30 | 28.10 | 29.89 | 31.68 |
| D/(Vb/Va) [μm] *D = 4.5 [μm] | 29.17 | 31.50 | 33.82 | 36.13 | 38.43 | 40.73 |
| D/(Vb/Va) [μm] *D = 5.0 [μm] | 32.41 | 35.00 | 37.58 | 40.14 | 42.70 | 45.26 |
| D/(Vb/Va) [μm] *D = 6.0 [μm] | 38.90 | 42.00 | 45.09 | 48.17 | 51.24 | 54.31 |

TABLE 3

| Material of Active Layer | AlInSb (Al Composition: 4.8%) | | | | | |
|---|---|---|---|---|---|---|
| Size of Pad Electrode | Equivalent of Nine Unit Elements | | | | | |
| Number of Unit Elements (Horizontal) | 9 | 10 | 11 | 12 | 13 | 14 |
| Number of Unit Elements (Vertical) | 9 | 10 | 11 | 12 | 13 | 14 |
| Total Number of Unit Elements | 63 | 82 | 103 | 126 | 151 | 178 |
| Maximum Shortcut Number of Adjacent Unit Elements | 17 | 19 | 21 | 23 | 25 | 27 |
| Vb/Va | 0.2698 | 0.2317 | 0.2039 | 0.1825 | 0.1656 | 0.1517 |
| Is Total Number of Unit Elements 70 or more? | No | Yes | Yes | Yes | Yes | Yes |
| Is Total Number of Unit Elements 200 or less? | Yes | Yes | Yes | Yes | Yes | Yes |
| Is 0.140 ≤ Vb/Va ≤ 0.261 Satisfied? | No | Yes | Yes | Yes | Yes | Yes |
| Is 0.190 ≤ Vb/Va ≤ 0.261 Satisfied? | No | Yes | Yes | No | No | No |
| D/(Vb/Va) [μm] *D = 3.5 [μm] | 12.97 | 15.11 | 17.17 | 19.17 | 21.14 | 23.07 |
| D/(Vb/Va) [μm] *D = 4.5 [μm] | 16.68 | 19.42 | 22.07 | 24.65 | 27.18 | 29.67 |
| D/(Vb/Va) [μm] *D = 5.0 [μm] | 18.53 | 21.58 | 24.52 | 27.39 | 30.20 | 32.96 |
| D/(Vb/Va) [μm] *D = 6.0 [μm] | 22.24 | 25.89 | 29.43 | 32.87 | 36.24 | 39.56 |

| Material of Active Layer | AlInSb (Al Composition: 4.8%) | | | | |
|---|---|---|---|---|---|
| Size of Pad Electrode | Equivalent of Nine Unit Elements | | | | |
| Number of Unit Elements (Horizontal) | 15 | 16 | 17 | 18 | 19 |
| Number of Unit Elements (Vertical) | 15 | 16 | 17 | 18 | 19 |
| Total Number of Unit Elements | 207 | 238 | 271 | 306 | 343 |
| Maximum Shortcut Number of Adjacent Unit Elements | 29 | 31 | 33 | 35 | 37 |
| Vb/Va | 0.1401 | 0.1303 | 0.1218 | 0.1144 | 0.1079 |
| Is Total Number of Unit Elements 70 or more? | Yes | Yes | Yes | Yes | Yes |
| Is Total Number of Unit Elements 200 or less? | No | No | No | No | No |
| Is 0.140 ≤ Vb/Va ≤ 0.261 Satisfied? | Yes | No | No | No | No |
| Is 0.190 ≤ Vb/Va ≤ 0.261 Satisfied? | No | No | No | No | No |
| D/(Vb/Va) [μm] *D = 3.5 [μm] | 24.98 | 26.87 | 28.74 | 30.60 | 32.45 |
| D/(Vb/Va) [μm] *D = 4.5 [μm] | 32.12 | 34.55 | 36.95 | 39.34 | 41.72 |
| D/(Vb/Va) [μm] *D = 5.0 [μm] | 35.69 | 38.39 | 41.06 | 43.71 | 46.35 |
| D/(Vb/Va) [μm] *D = 6.0 [μm] | 42.83 | 46.06 | 49.27 | 52.46 | 55.62 |

As described above, the infrared optical element according to this embodiment can improve resistance to short-circuiting caused by ESD by satisfying the above-described conditions regarding the wiring pattern that connects a large number of photoelectric conversion elements in series, the voltage Va, the maximum potential difference Vb, and the creepage distance D.

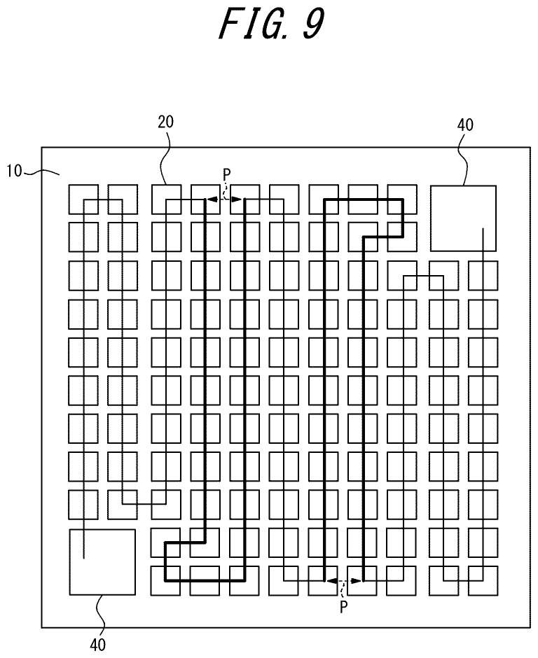

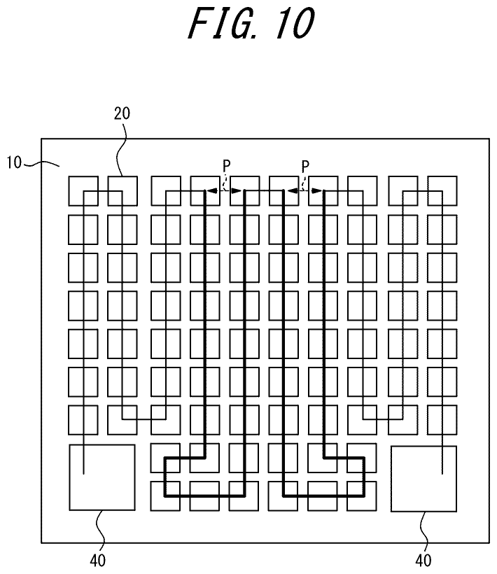

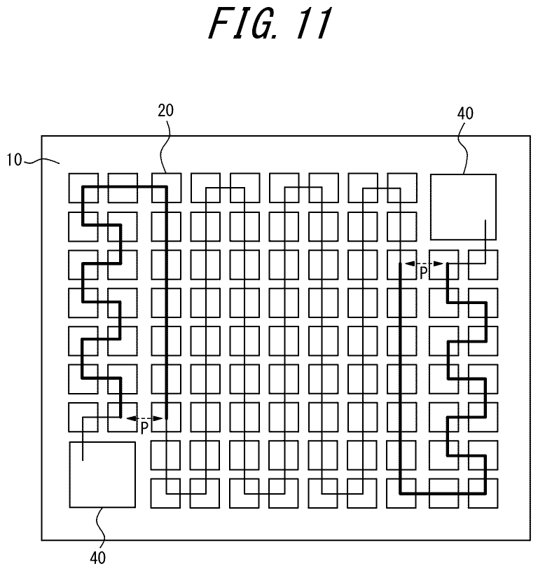

The arrangement and the like of the unit elements 20 and the pad electrodes 40 are not limited to the above examples. For example, the numbers of unit elements 20 in the vertical and horizontal directions may be the same or different. The multiple pad electrodes 40 may be located diagonally at the corners of a chip or different sides of the chip, and the maximum number of unit elements 20 arranged in a direction to which the maximum potential difference is applied may be an odd number (see FIGS. 9 and 11). The multiple pad electrodes 40 may be located on the same side of a chip, and the maximum number of unit elements 20 arranged in a direction to which the maximum potential difference is applied may be an even number (see FIG. 10). The multiple pad electrodes 40 may be located diagonally at the corners of a chip or different sides of the chip, and the connection of the unit elements 20 may be point-symmetrical with respect to the center of the chip (see FIG. 9). The multiple pad electrodes 40 may be located on the same side of a chip, and the connection of the unit elements 20 may be line-symmetrical with respect to the center line of two of the pad electrodes 40 (see FIG. 10). There may be multiple locations within a single chip at which the maximum potential difference occurs. The maximum number of unit elements 20 arranged in a direction to which the maximum potential difference is applied may be 9 or more and 14 or less, for example.

Here, the wiring pattern of the unit elements 20 can be distinguished from external appearance. When the cross-sectional structure is the same within a chip, the ratio of the maximum potential difference to the applied voltage can be calculated from the size of the unit elements 20, the wiring pattern, and the distance of the insulating portions 60 (insulating parts). In addition, when an ESD test (e.g., machine model (MM), human body model (HBM), charged device model (CDM)) is performed, ESD breakdown occurs at points at which the maximum potential difference is applied. Therefore, by checking the points of the breakdown using visual inspection or the optical beam induced resistance change (OBIRCH) test, it is possible to identify where the maximum potential difference occurs. In addition, by measuring the resistance between unit elements 20 using a micro probe or the like, more specifically, by measuring the resistance of the entire chip and the resistance between the unit elements 20 between which the maximum potential difference is applied, it is possible to estimate the ratio of the maximum potential difference to the applied voltage.

### Second Embodiment

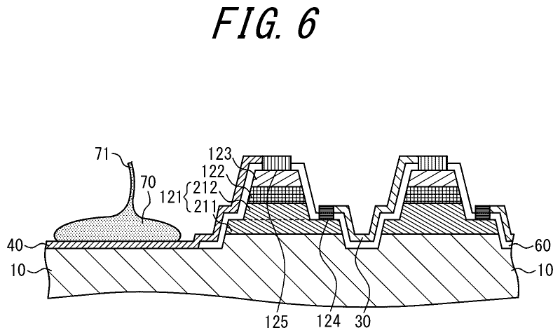

In an infrared optical element according to a second embodiment, a structure that can achieve both improvement in a resistance drop and increase in a signal-to-noise ratio (SNR) is further added to the infrared optical element according to the first embodiment. A schematic diagram (plan view) of the infrared optical element according to the second embodiment is FIG. 1, the same as that of the first embodiment. A description of FIG. 1 is omitted to avoid repetition. FIG. 6 is a partial cross-sectional view of the infrared optical element according to the second embodiment.

### (Substrate)

A substrate 10 according to this embodiment has no restrictions on doping by donor impurities or acceptor impurities. However, from the viewpoint of enabling multiple unit elements 20 formed on the substrate 10 to be connected in series, it is desirable that the substrate 10 is semi-insulating or can be insulated and separated from second conductive semiconductor layers 121.

Here, when light is incident on or emitted from the side of the substrate 10, it is necessary to use, as the substrate 10, a material with a larger band gap than active layers 122. As an example, the substrate 10 may be a GaAs substrate, a Si substrate, an InP substrate, or an InSb substrate, but is not limited to these.

### (Unit Element)

Each unit element 20 includes a second conductive semiconductor layer 121 disposed on the substrate 10, an active layer 122 disposed on the second conductive semiconductor layer 121, and a first conductive semiconductor layer 123 disposed on the active layer 122. As described in this embodiment, the infrared optical element may be configured with the multiple unit elements 20 that are electrically connected in series.

### (Mesa Structure)

As illustrated in FIG. 6, the first conductive semiconductor layer 123, the active layer 122, and the second conductive semiconductor layer 121 form a mesa structure.

The mesa structure is not particularly limited as long as the mesa structure includes a photodiode structure with a PN junction or a PIN junction. The first conductive semiconductor layer 123 and the second conductive semiconductor layer 121 are of opposite conductive types. For example, when the first conductive semiconductor layer 123 is an n-type, the second conductive semiconductor layer 121 is a p-type. For example, when the first conductive semiconductor layer 123 is a p-type, the second conductive semiconductor layer 121 is an n-type. The material of the first conductive semiconductor layer 123 and the second conductive semiconductor layer 121 is InSb, InAsSb, AlInSb, or the like, but is not limited to these. Here, the assignment of the p-type or n-type may be determined according to the material. For example, when the material is InSb and the material of contact electrodes is Ti, the p-type tends to have high contact resistance (Schottky contact) and the n-type tends to have low contact resistance (ohmic contact). When a contact portion on the p-type is small, contact resistance may become too high, so in such a material combination, the first conductive semiconductor layer 123 may be selected to be of the p-type. The first conductive semiconductor layer 123 and the second conductive semiconductor layer 121 may have laminated structures made of multiple materials. The active layer 122 preferably contains In and Sb, as constituent elements. As a specific example, the material of the active layer 122 may be InSb or AlInSb. In this embodiment, each of the first conductive semiconductor layer 123, the active layer 122, and the second conductive semiconductor layer 121 is made of a material containing In and Sb.

### (Contact Electrode)

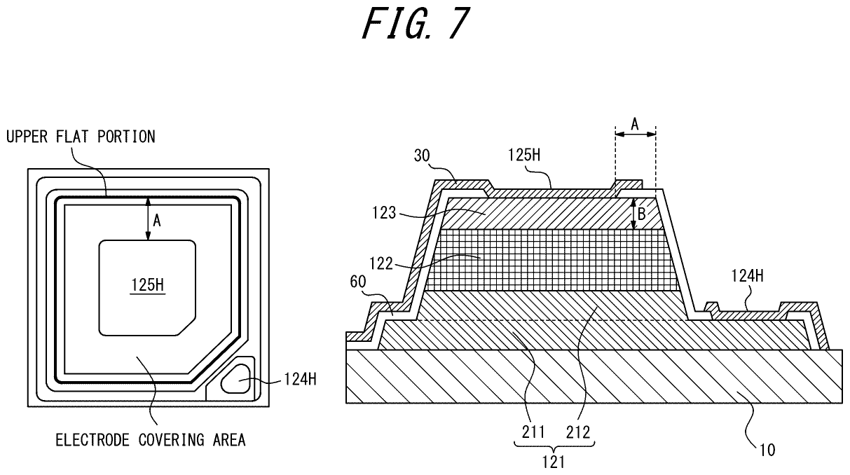

The infrared optical element according to this embodiment includes first contact electrode portions 125 each disposed on the first conductive semiconductor layer 123, and second contact electrode portions 124 each disposed on a first region 211 of the second conductive semiconductor layer 121. The material of the contact electrodes (the first contact electrode portions 125 or the second contact electrode portions 124) preferably has low contact resistance to the semiconductor layers and low electric resistance. As a specific example, the material of the contact electrodes may be Ti, Ni, Pt, Cr, Al, Cu, Au, or the like. The contact electrodes may be made of laminates of multiple types of materials. In this embodiment, the first contact electrode portions 125 and the second contact electrode portions 124 contain Ti (titanium) as a material. The contact electrodes are also covered with protective films for protection. There is an electrode covering area, in which the first contact electrode portion 125 is covered, inside an upper flat portion of the mesa structure of each unit element 20 (see FIG. 7).

### (Contact Portion)

Each unit element 20 further includes a first contact portion 125H (see FIG. 7) that electrically connects the first conductive semiconductor layer 123 and the first contact electrode portion 125. Each unit element 20 further includes a second contact portion 124H (see FIG. 7) that electrically connects the second conductive semiconductor layer 121 and the second contact electrode portion 124.

### (Internal Wiring Portion)

The infrared optical element according to this embodiment includes internal wiring portions 30 each of which connects the second contact electrode portion 124 of a single unit element 20 and the first contact electrode portion 125 of another unit element 20 that is adjacent and electrically connected to that unit element 20. In other words, the internal wiring portions 30 electrically connect the multiple unit elements 20 in series. The material of the internal wiring portions 30 preferably has low electric resistance. As a specific example, the material of the internal wiring portions 30 may be Ti, Ni, Pt, Cr, Al, Cu, Au, or the like.

### (Insulating Portion)

The unit elements 20 of the infrared optical element according to this embodiment may further include an insulating portion 60 so that side surfaces of the mesa structures are not electrically connected to the internal wiring portions 30 in a direct manner. The insulating portion 60 is disposed between first mesa structures (each constituted of a second region 212, the active layer 122, and the first conductive semiconductor layer 123) and the internal wiring portions 30, and between second mesa structures (each constituted of the first region 211 and part of the substrate 10) and the internal wiring portions 30. The material of the insulating portion 60 may be silicon nitride, silicon oxide, aluminum oxide, or the like, but is not limited to these. The insulating portion 60 may be made of a laminate of multiple types of materials.

### (Pad Electrode)

Pad electrodes 40 are electrically connected to a device or the like outside the infrared optical element via connection portions 70 and connection wires 71. The infrared optical element according to this embodiment has such a configuration that the multiple pad electrodes 40 and the multiple unit elements 20 are electrically connected in series with the pad electrodes 40 being located at both ends. The material of the pad electrodes 40 preferably has low electric resistance. As a specific example, the material of the pad electrodes 40 may be Ti, Ni, Pt, Cr, Al, Cu, Au, or the like. The pad electrodes 40 may be made of a material different from that of the contact electrodes.

### (Connection Portion)

As described above, the connection portions 70 are provided for electrically connecting to the outside. As a specific example, the connection portions 70 may be made of metal and conductive adhesive. For example, the connection portions 70 and the connection wires 71 may be wire-bonded onto the pad electrodes 40.

Here, in the infrared optical element having the unit elements 20 with the mesa structures, as described above, when a resistance drop occurs due to side leakage (leakage of current to the sides of the mesa structures), the performance of the optical element deteriorates. For example, by reducing the size (area) of the first contact electrode portion 125 and arranging the first contact electrode portion 125 near the center of the upper flat portion of the mesa structure, when viewed from above, the distance to the sides can be increased and the side leakage can be reduced. However, it is known that making the size of the first contact electrode portion 125 too small causes reduction in an SNR. Therefore, there are appropriate conditions for achieving both an improved resistance drop and an increased SNR in the design of the unit element 20, but quantitative conditions have not been conventionally specified. The inventor has actively examined and confirmed that both an improved resistance drop and an increased SNR can be achieved when predetermined relationships regarding the area of the contact portion, the ratio of an area covered by the first contact electrode portion 125, and the ratio between shortest distance A to thickness B, as explained below, are satisfied. A method of providing an infrared optical element with an improved resistance drop and an increased SNR (in other words, an infrared optical element that provides a good SNR while suppressing side leakage of the mesa structures) will be described below.

FIG. 7 is a diagram that explains the configuration of the contact portions and the like in the mesa structure. The left diagram in FIG. 7 is a plan view of the mesa structure. The right diagram in FIG. 7 is a cross-sectional diagram illustrating a cross-section including the first contact portion 125H and the second contact portion 124H of the left diagram. The right diagram in FIG. 7 corresponds to a cross-sectional diagram of the single unit element 20 in FIG. 6, excluding the first contact electrode portion 125 and the second contact electrode portion 124. The same reference numerals are assigned to elements common to FIGS. 1 and 6, and descriptions are omitted. Here, the upper flat portion of the mesa structure refers to a flat portion at an upper portion of the mesa structure, up to the points just before the slopes of the mesa structure (before reaching the slopes). The upper flat portion of the mesa structure may be an area that overlaps an upper portion of the first conductive semiconductor layer 123 when viewed from above. Inside the upper flat portion, there is an electrode covering area in which the first contact electrode portion 125 is covered. The upper portion of the mesa structure may be regarded as flat even when there are irregularities of 5% or less with respect to the thickness of the entire mesa structure in a cross-sectional view. The upper portion of the mesa structure may be regarded as flat even when there are irregularities of 400 nm or less in a cross-sectional view.

The appropriate conditions for achieving both an improved resistance drop and an increased SNR are as follows. First, the shortest distance A from an end of the upper flat portion of the mesa structure to an end of the first contact portion 125H when viewed from above is determined. The thickness B of the first conductive semiconductor layer 123 is determined in a cross-sectional view. At this time, the mesa structure is configured so that the ratio (A/B) between the shortest distance A and the thickness B is 14 or more. The mesa structure may be configured so that the ratio (A/B) is 12 or more. This condition is set to effectively improve a resistance drop due to side leakage.

The mesa structure is also configured so that the area of the first contact portion 125H is 6% or more, preferably 13% or more of the area of the upper flat portion, when viewed from above. This condition is also set to prevent the occurrence of reduction in an SNR.

The mesa structure may also be configured so that the area of the first contact portion 125H is three or more times the area of the second contact portion 124H when viewed from above. This condition is set because making the area of the first contact portion 125H too small causes reduction in an SNR. Here, in the single mesa structure, there may be multiple first contact portions 125H. In this case, the total area of the multiple first contact portions 125H is configured to be three or more times the area of the second contact portion 124H. The area ratio may be even larger, and the mesa structure may be configured so that the area of the first contact portion 125H is five or more times the area of the second contact portion 124H, for example.

The mesa structure may also be configured so that 50% or more of the area of the upper flat portion of the mesa structure is covered by the first contact electrode portion 125. This condition is also set to prevent the occurrence of reduction in an SNR.

For example, as illustrated in the following experimental example, configuring the mesa structure to satisfy these conditions can achieve both an improved resistance drop and an increased SNR. In other words, the appropriate conditions are that the ratio (A/B) is 14 or more, and that the area of the first contact portion 125H is 6% or more of the upper flat portion. For the mesa structure, the appropriate conditions may further include at least one of that the area ratio between the contact portions is at least 3 or more times, or that the electrode portion covers 50% or more of the upper flat portion.

In order to increase the distance to the sides and prevent the occurrence of side leakage, the shortest distance A is preferably set to 1.4 μm or more. Furthermore, the shortest distance A is preferably set to 6 μm or more, more preferably set to 7 μm or more, and even more preferably set to 10 μm or more. In order to prevent performance degradation, the shortest distance A is preferably set to 20 μm or less.

Here, in order to improve mass productivity, the thickness B is preferably set to 0.1 μm or more. The thickness B is more preferably set to 0.5 μm or more. In order to improve mass productivity, the thickness B is preferably set to 2 μm or less.

In order to increase the distance to the sides and prevent the occurrence of side leakage, the area of the first contact portion 125H is preferably 65% or less of the area of the electrode covering area, when viewed from above.

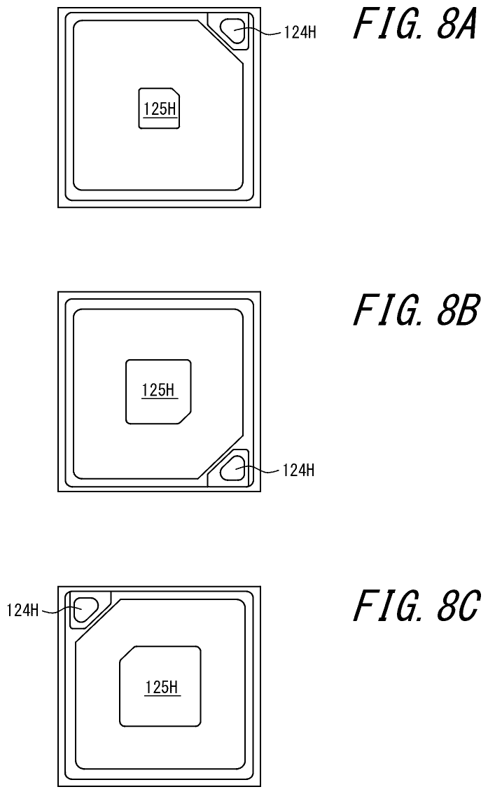

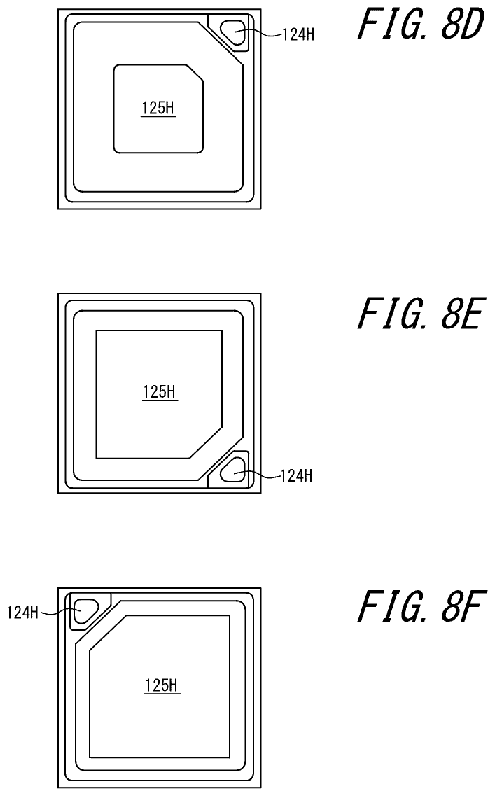

Table 4 below illustrates the results of the experiment in which, in the mesa structure of the unit element 20, the size of the first contact portion 125H (first contact electrode portion 125) was changed, and improvement in a resistance drop and increase in an SNR were evaluated. FIGS. 8A to 8F illustrate upper portions of mesa structures of unit elements 20 Numbers 1 to 6, respectively. In other words, FIG. 8A illustrates the shape of the upper portion of the mesa structure Number 1 when viewed from above, FIG. 8B illustrates that Number 2, FIG. 8C illustrates that Number 3, FIG. 8D illustrates that Number 4, FIG. 8E illustrates that Number 5, and FIG. 8F illustrates that Number 6. The size of the first contact portion 125H was set to increase in the order of Numbers 1 to 6. The effectiveness of an increased SNR and the effectiveness of an improved resistance drop were evaluated based on the unit element 20 Number 6. In other words, those that were improved compared to the unit element 20 Number 6 were indicated as “effective”. As illustrated in Table 4, a resistance drop was improved and an SNR was increased in the unit elements 20 Numbers 2 to 5, which satisfied the above-described appropriate conditions. In other words, it was confirmed that it is possible to achieve both an improved resistance drop and an increased SNR by designing the mesa structure of the unit element 20 to satisfy the above conditions.

| | 1 | 2 | 3 | 4 | 5 | 6 |
|---|---|---|---|---|---|---|
| Number (Corresponding Drawing) | (FIG. 8A) | (FIG. 8B) | (FIG. 8C) | (FIG. 8D) | (FIG. 8E) | (FIG. 8F) |
| Area of First Contact Portion/Area of Second Contact Portion | 3.6 | 10.5 | 18.2 | 24.4 | 39.5 | 53.2 |
| Area of First Contact Electrode Portion/Area of Upper Flat Portion | 78.4% | 78.4% | 78.4% | 78.4% | 78.4% | 78.4% |
| Shortest Distance A [μm] | 20.5 | 16.5 | 13.5 | 11.5 | 7.5 | 4.5 |
| Area of First Contact Portion/Area of Upper Flat Portion | 4.6% | 13.6% | 23.4% | 31.4% | 50.8% | 68.6% |
| Area of First Contact Portion/Area of Electrode Covering Area | 5.9% | 17.3% | 29.8% | 40.0% | 64.9% | 87.5% |
| Shortest Distance A/Thickness B | 41 | 33 | 27 | 23 | 15 | 9 |
| Effectiveness of Increased SNR | Ineffective | Effective | Effective | Effective | Effective | Ineffective |
| | | | | | | (Reference) |
| Effectiveness of Improved Resistance Drop | Effective | Effective | Effective | Effective | Effective | Ineffective |
| | | | | | | (Reference) |

As described above, the infrared optical element according to this embodiment can achieve both an improved resistance drop and an increased SNR by determining the size of the first contact portion 125H and the like.

The embodiments of the present disclosure have been described based on various drawings and examples, but it should be noted that a person skilled in the art would be able to easily make various variations or modifications based on the present disclosure. Therefore, these variations or modifications are included within the scope of the present disclosure.

1. An infrared optical element comprising:
a substrate; and
a unit element,
wherein
the unit element comprises:
a second conductive semiconductor layer disposed on the substrate;
an active layer disposed on the second conductive semiconductor layer; and
a first conductive semiconductor layer disposed on the active layer,
the first conductive semiconductor layer, the active layer, and the second conductive semiconductor layer configure a mesa structure,
the unit element further comprises:
a first contact portion that electrically connects the first conductive semiconductor layer and a first contact electrode portion; and
a second contact portion that electrically connects the second conductive semiconductor layer and a second contact electrode portion,
a ratio (A/B) between a shortest distance A from an end of an upper flat portion of the mesa structure to an end of the first contact portion and a thickness B of the first conductive semiconductor layer is 14 or more, and
an area of the first contact portion is 6% or more of an area of the upper flat portion.

2. An infrared optical element comprising:
a substrate; and
a unit element,
wherein
the unit element comprises:
a second conductive semiconductor layer disposed on the substrate;
an active layer disposed on the second conductive semiconductor layer; and
a first conductive semiconductor layer disposed on the active layer,
the first conductive semiconductor layer, the active layer, and the second conductive semiconductor layer configure a mesa structure,
the unit element further comprises:
a first contact portion that electrically connects the first conductive semiconductor layer and a first contact electrode portion; and
a second contact portion that electrically connects the second conductive semiconductor layer and a second contact electrode portion,
a shortest distance A from an end of an upper flat portion of the mesa structure to an end of the first contact portion is 7 μm or more, and
an area of the first contact portion is 6% or more of an area of the upper flat portion.

3. The infrared optical element according to claim 1, wherein the area of the first contact portion is 3 or more times an area of the second contact portion.

4. The infrared optical element according to claim 1, wherein 50% or more of the area of the upper flat portion of the mesa structure is covered by the first contact electrode portion.

5. The infrared optical element according to claim 2, wherein the shortest distance A is 10 μm or more.

6. The infrared optical element according to claim 1, wherein the area of the first contact portion is 5 or more times an area of the second contact portion.

7. The infrared optical element according to claim 1, wherein the area of the first contact portion is 65% or less of an area of an electrode covering area inside the upper flat portion.

8. The infrared optical element according to claim 1, wherein the first contact electrode portion and the second contact electrode portion contain titanium as a material.

9. The infrared optical element according to claim 1, wherein the unit element comprises multiple first contact portions.

10. The infrared optical element according to claim 1, wherein the area of the first contact portion is 13% or more of the area of the upper flat portion.
